(19) United States
(12) Patent Application Publication
(10) Pub. No.: US 2026/0024587 A1
(43) Pub. Date: Jan. 22, 2026

(54) RESUMING AN ERASE OPERATION SUSPENDED DURING A PRE-PROGRAM PHASE BASED ON A VERIFY OPERATION RESULT

(71) Applicant: Micron Technology, Inc., Boise, ID (US)

(72) Inventors: Sanjoy Jena, Singapore (SG); Narayanan Ramanan, Hyderabad (IN); Shyam Sundar Raghunathan, Singapore (SG); Kapil Verma, San Jose, CA (US)

(21) Appl. No.: 19/262,859

(22) Filed: Jul. 8, 2025

Related U.S. Application Data
(60) Provisional application No. 63/674,042, filed on Jul. 22, 2024.

(51) Int. Cl. G11C 16/14; G11C 16/04; G11C 16/34

(52) U.S. Cl. CPC G11C 16/14; G11C 16/344; G11C 16/0483

(57) ABSTRACT

A memory device including a memory array and control logic, operatively coupled with the memory array, to perform operations including causing execution of an erase operation to erase a set of memory cells of the memory array. A request to suspend the erase operation during a pre-program phase of the erase operation is identified. A resume operation is caused to be executed to resume the erase operation, where the resume operation includes a verify operation. An action is caused to be executed based on a result of the verify operation.

### CROSS-REFERENCE TO RELATED APPLICATION

This application claims the benefit of U.S. Provisional Application No. 63/674,042, titled “Resuming a Suspended Erase Operation Suspended During a Pre-program Phase Based on a Verify Operation Result”, filed Jul. 22, 2024, which is hereby incorporated herein by reference in its entirety.

### TECHNICAL FIELD

Embodiments of the disclosure relate generally to memory sub-systems, and more specifically, relate to resuming a suspended erase operation suspended during a pre-program phase based on a result of a verify operation executed based on a measured parameter level associated with one or more memory cells being erased.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system in accordance with one or more embodiments of the present disclosure.

FIG. 1B is a block diagram of a memory device in communication with a memory sub-system controller of a memory sub-system in accordance with one or more embodiments of the present disclosure.

FIGS. 2A-2C are diagrams of portions of an example array of memory cells included in a memory device, in accordance with one or more embodiments of the present disclosure.

FIG. 3 illustrates an example flow diagram associated with a process for resuming a suspended erase operation associated with one or more memory cells of a memory device of a memory sub-system, where the initial erase operation was previously suspended during a pre-program (PPGM) phase of the erase operation, according to one or more embodiments of the present disclosure.

FIG. 4 depicts a table representing an example verify operation executed by control logic during a resume operation associated with an erase operation suspended during a PPGM stage, according to one or more embodiments of the present disclosure.

FIG. 5 is a flow diagram of a method to cause execution of a resume operation to resume an erase operation that was previously suspended during a pre-program phase of the erase operation, where the resume operation includes performing an action based on a result of a verify operation, according to one or more embodiments of the present disclosure.

FIG. 6 is a block diagram of an example computer system in which embodiments of the present disclosure may operate.

### DETAILED DESCRIPTION

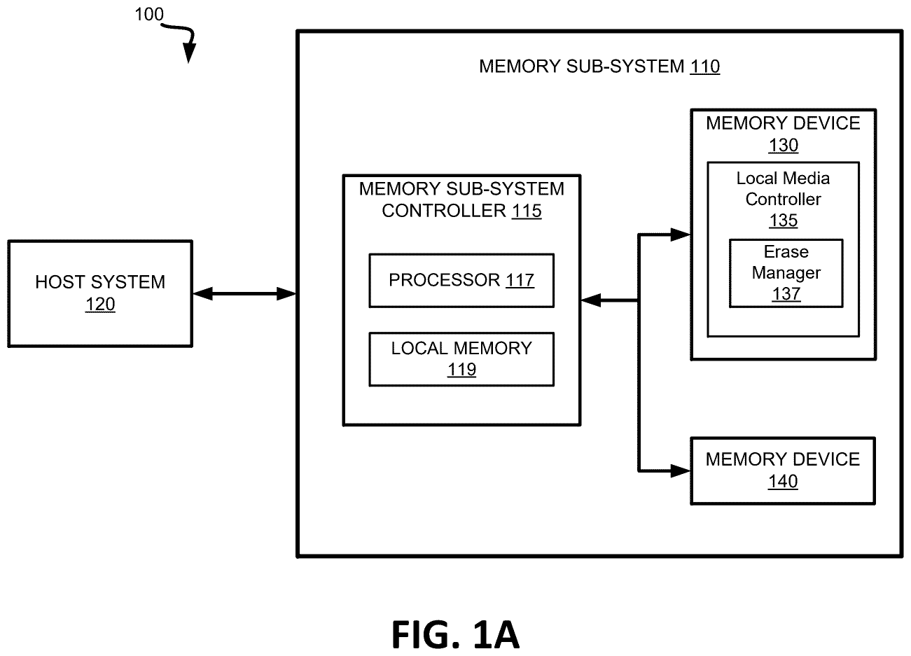

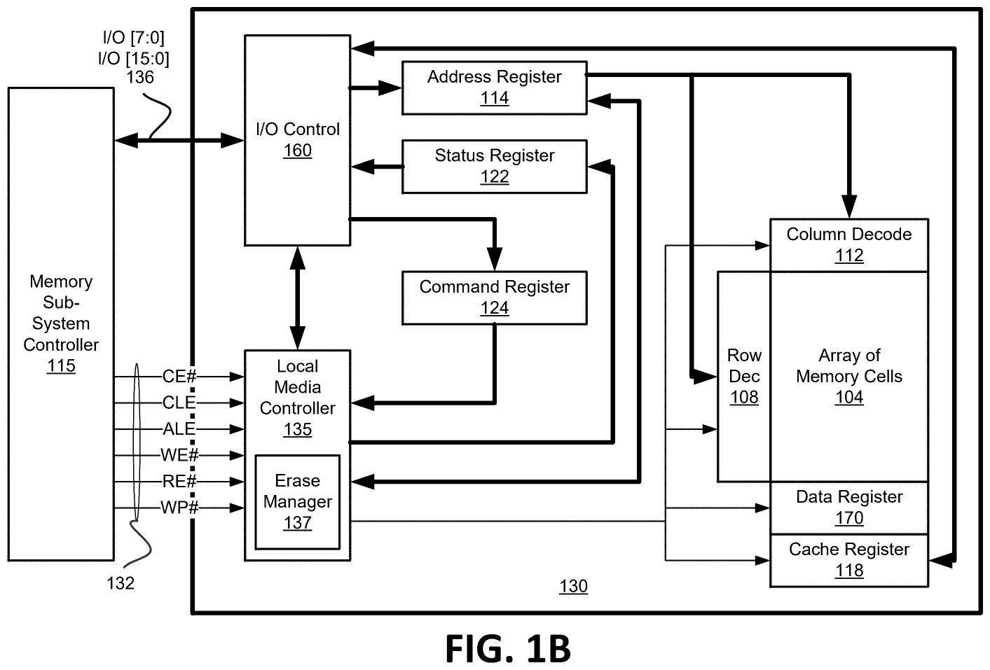

Aspects of the present disclosure are directed to resuming a suspended erase operation based on a result of a verify operation executed based on a measured parameter level associated with one or more memory cells in a memory device of a memory sub-system. A memory sub-system can be a storage device, a memory module, or a combination of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIGS. 1A-1B. A non-volatile memory device is a package of one or more dies. Each die can consist of one or more planes. For some types of non-volatile memory devices (e.g., NAND devices), each plane consists of a set of physical blocks. Each block consists of a set of pages. Each page consists of a set of memory cells. A memory cell is an electronic circuit that stores information. Depending on the memory cell type, a memory cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or three-dimensional grid. The memory cells are formed onto a silicon wafer in an array of columns (also hereinafter referred to as bitlines) and rows (also hereinafter referred to as wordlines). A wordline can refer to one or more conductive lines of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types. For case of description, these circuits can be generally referred to as independent plane driver circuits. Control logic on the memory device includes a number of separate processing threads to perform concurrent memory access operations (e.g., read operations, program operations, and erase operations). For example, each processing thread corresponds to a respective one of the memory planes and utilizes the associated independent plane driver circuits to perform the memory access operations on the respective memory plane. As these processing threads operate independently, the power usage and requirements associated with each processing thread also varies.

A memory device can be a three-dimensional (3D) memory device. For example, a 3D memory device can be a three-dimensional (3D) replacement gate memory device (e.g., 3D replacement gate NAND), which is a memory device with a replacement gate structure using wordline stacking. For example, a 3D replacement gate memory device can include wordlines, select gates, etc. located between sets of layers including a pillar (e.g., polysilicon pillar), a tunnel oxide layer, a charge trap (CT) layer, and a dielectric (e.g., oxide) layer. A 3D replacement gate memory device can have a “top deck” corresponding to a first side and a “bottom deck” corresponding to a second side. For example, the first side can be a drain side and the second side can be a source side. Data in a 3D replacement gate memory device can be stored as 1 bit/memory cell (SLC), 2 bits/memory cell (MLC), 3 bits/memory cell (TLC), etc.

In certain memory sub-systems it is common to receive a request from a host system to perform a memory access operation (e.g., a program operation, a read operation, etc.) while an erase operation is in progress. The erase operation includes a sequence of phases, including a partial-block erase (PBE) phase, a pre-program (PPGM) phase, an erase pulse phase, and an erase verify (TEV) phase. In response to receipt of a request to execute another memory access operation during execution of an erase operation, an erase suspend operation is initiated. The erase suspend operation allows the ongoing erase operation to be suspended to enable execution of the higher priority memory access operation (e.g., a program operation or a read operation) to be executed. Following completion of the memory access operation, the previously suspended erase operation can be resumed.

In certain systems, the PPGM phase can include the application of a ramping voltage to the one or more memory cells being erased (referred to as the “ramping stage” of the PPGM phase or “PPGM ramping stage”), followed by a stage where a constant voltage is applied (referred to as the “flattop stage” of the PPGM phase). In certain systems, control logic can check to determine if a suspend operation has been requested at various checkpoints (i.e., suspend points) during the application of a ramping voltage (i.e., during the ramping stage) of the PPGM phase of the erase operation. In such systems, the erase operation can be suspended immediately at any of a series of voltage checkpoints arranged along the ramping voltage of the ramping stage of the PPGM phase, up until a last checkpoint (also referred to as a “last checkpoint” of the ramping portion of the PPGM phase). If the suspend operation request is identified after the last checkpoint, the suspend operation is delayed until after the remaining ramping phase and the corresponding voltage flattop portion of the PPGM are completed. This delay in the execution of the suspend operation until the ramp and flattop phases are completed results in an undesirable increase in a wait time between the suspend operation request and the execution of the suspend operation (also referred to as “a suspend wait time” (T_{espd})). The increased wait time (increased T_{espd}) results in the delayed execution of the desired memory access operation requested by the host system.

After suspending on the PPGM ramp portion, the resume operation again begins with the ramping portion of the PPGM phase. In some systems, to reduce the suspend wait time (T_{espd}) associated with receiving the suspend operation request after the last checkpoint of the ramping portion of the PPGM phase, the last checkpoint may be increased (i.e., set to a higher voltage along the voltage ramp). However, increasing the last checkpoint to a higher voltage results in a higher PPGM threshold voltage, which undesirably increases trap-up related reliability issues in the suspend-resume-usage workloads of the memory device.

Aspects of the present disclosure address the above and other deficiencies by managing a resume operation following suspension of an erase operation occurring during a ramping stage of a pre-program phase (PPGM phase) of the erase operation by executing a verify operation (also referred to as a “verify operation” or a “PPGM verify operation”). According to embodiments, in response to a request to execute a memory access operation identified during the PPGM ramp phase of the erase operation, a suspend operation is executed. Following completion of the requested memory access operation, the erase operation is resumed by executing a resume operation including a verify operation to measure or check of a parameter associated with the erase operation (e.g., a measurement of a threshold voltage level or a measurement of a count failure byte (CFByte) level).

According to embodiments, the verify operation determines if the measured parameter (e.g., the CFByte level) satisfies a first condition. In an embodiment, the first condition is satisfied if the measured parameter is greater than a first threshold level. In an embodiment, if the first condition is satisfied, the PPGM phase of the erase operation is performed with a ramping portion followed by a normal or original flattop portion in accordance with a normal or original erase operation. In an embodiment, the normal or original flattop portion includes application of a constant voltage level (i.e., a first program level) for a first duration.

According to embodiments, if the first condition is not satisfied (i.e., the measured parameter is less than the first threshold), the verify operation determines if the measured parameter satisfies a second condition. In an embodiment, the second condition is satisfied if the measured parameter is greater than a second threshold level, where the second threshold level is less than the first threshold level. In an embodiment, if the second condition is satisfied, the PPGM phase of the erase operation is performed with a ramping portion followed by an adjusted flattop portion. In an embodiment, the adjusted flattop portion includes application of a constant voltage level for a second duration, where the second duration is less than the first duration. Advantageously, execution of the resumed erase operation including the adjusted flattop portion reduces the overprogramming of the one or more memory cells being erased. In an embodiment, if both the first condition and the second condition are not satisfied, the PPGM phase of the resumed erase operation is skipped (i.e., not performed), such that the resumed erase operation initiates with the erase pulse ramping stage.

In another embodiment, if the second condition is satisfied, the adjusted flattop portion includes application of a constant program level of a second program level, where the second program level is less than the first program level (i.e., a program level applied during the flattop portion in a normal erase operation).

Advantages of the present disclosure include, but are not limited to, improved memory sub-system performance and quality of service (QOS). For example, employing the verify operation as part of the resumed erase operation (following a suspension to execute a requested a higher-priority memory access operation) enables the elimination of the use of PPGM checkpoints. Accordingly, when the suspend operation request is received at any time during the PPGM ramping stage of the PPGM phase of the erase operation, the erase operation is suspended substantially immediately, which reduces the suspend wait time (T_{espd}). In addition, according to embodiments, the resumed erase operation includes the execution of the verify operation during which a parameter level or value is measured and compared to a first threshold level and a second threshold level to determine if a first condition and a second condition are satisfied. A further advantage is achieved in response to satisfaction of the conditions by adjusting a duration of the flattop stage of the PPGM phase (e.g., the duration of the flattop stage is reduced as compared to a normal erase operation) or a reduced PPGM program voltage (e.g., the program voltage of the second pulse applied during the PPGM ramping stage, which reduces overprogramming of the one or more memory cells being erased.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a computer express link (CXL) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCS, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

According to embodiments, the local media controller 135 includes an erase manager 137 configured to execute a resume operation to resume an erase operation that was suspended during a PPGM stage, where the resume operation includes a verify operation. Upon resuming the erase operation, the verify operation is executed. In an embodiment, the verify operation includes measuring a parameter level (e.g., a CFByte level or a threshold voltage level) associated with the one or more memory cells being erased. In an embodiment, the erase manager 137 compares the measured parameter level (e.g., a measured CFByte level) to a first threshold level (e.g., CFByte_high) to determine if a first condition is satisfied. In an embodiment, the erase manager 137 determines the first condition is satisfied if the measured CFByte level is greater than the first threshold level (e.g., CFByte_high). In response to determining that the first condition is satisfied, the erase manager 137 causes the PPGM phase of the resumed erase operation to be executed with a PPGM ramping stage followed by a flattop stage having a first duration and a first program level. In an embodiment, the first duration and first program level of the flattop stage of the resumed erase operation are the same as the duration and program level of the original erase operation, respectively.

According to embodiments, if the first condition is not satisfied, the erase manager 137 compares the measured parameter level (e.g., the measured CFByte level) to a second threshold level (e.g., CFByte_low) to determine if a second condition is satisfied. In an embodiment, the erase manager 137 determines the second condition is satisfied if the measured CFByte level is greater than the second threshold level (e.g., CFByte_low). In response to determining that the second condition is satisfied, the erase manager 137 causes the PPGM phase of the resumed erase operation to be executed with a PPGM ramping stage followed by an adjusted flattop stage having a second duration, where the second duration of the adjusted flattop portion is less than the first duration (e.g., a duration of the flattop stage of a normal (non-suspended) erase operation). Advantageously, adjusting the duration of the flattop stage to a shorter duration as compared to a normal erase operation reduces overprogramming of the one or more memory cells being erased.

In another embodiment, if the first condition is not satisfied and the second condition is satisfied, the erase manager 137 causes the PPGM phase of the resumed erase operation to be executed with a PPGM ramping stage followed by an adjusted flattop stage having a second program level, where the second program level of the adjusted flattop portion is less than the first program level (e.g., a program level of the flattop stage of a normal (non-suspended) erase operation). Advantageously, adjusting the PPGM program level of the flattop stage to a smaller program level as compared to a normal erase operation reduces overprogramming of the one or more memory cells being erased.

In an embodiment, if neither the first condition nor the second condition are satisfied (i.e., the measured parameter level is less than both the first threshold level and the second threshold level), the erase manager 137 causes the PPGM phase of the resumed erase operation to be skipped, and proceeds to the erase pulse ramping stage of the resumed erase operation. Further details regarding the execution of a resuming a suspended erase operation by executing a verify operation are described below with reference to FIGS. 1B-6.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 112 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 112 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 112 to control the row decode circuitry 108 and column decode circuitry 112 in response to the addresses. In one embodiment, local media controller 135 includes the erase manager 137, which can resume a suspended erase operation based on results of a verify operation associated with the one or more memory cells of the memory device 130 that are being erased.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 170 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 170 to the cache register 118. The cache register 118 and/or the data register 170 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command register 124. The addresses may be received over input/output (I/O) pins [7:0] of I/O bus 136 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 170 for programming the array of memory cells 104.

In an embodiment, cache register 118 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

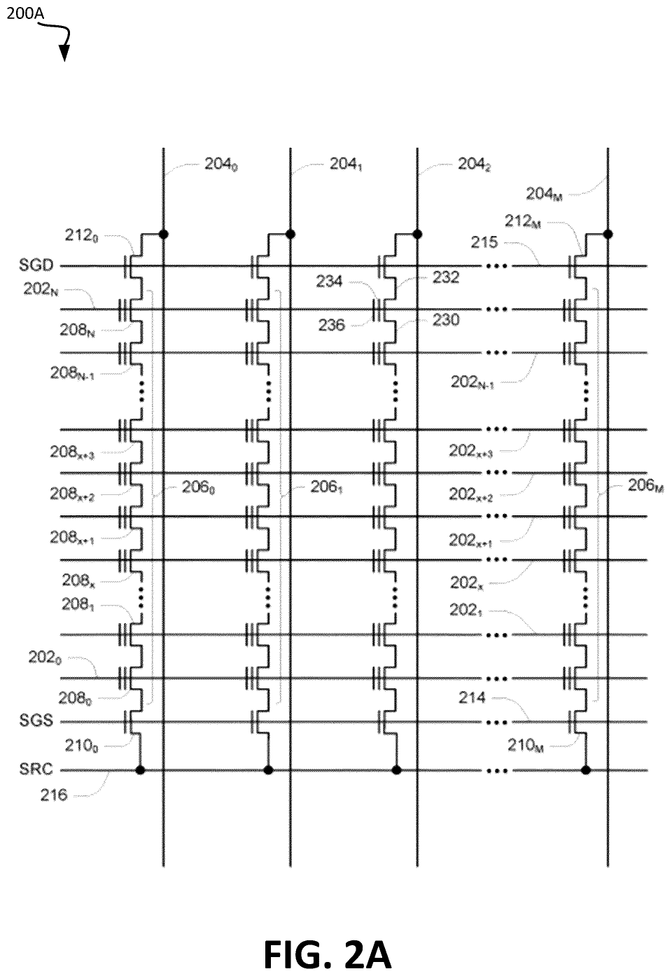

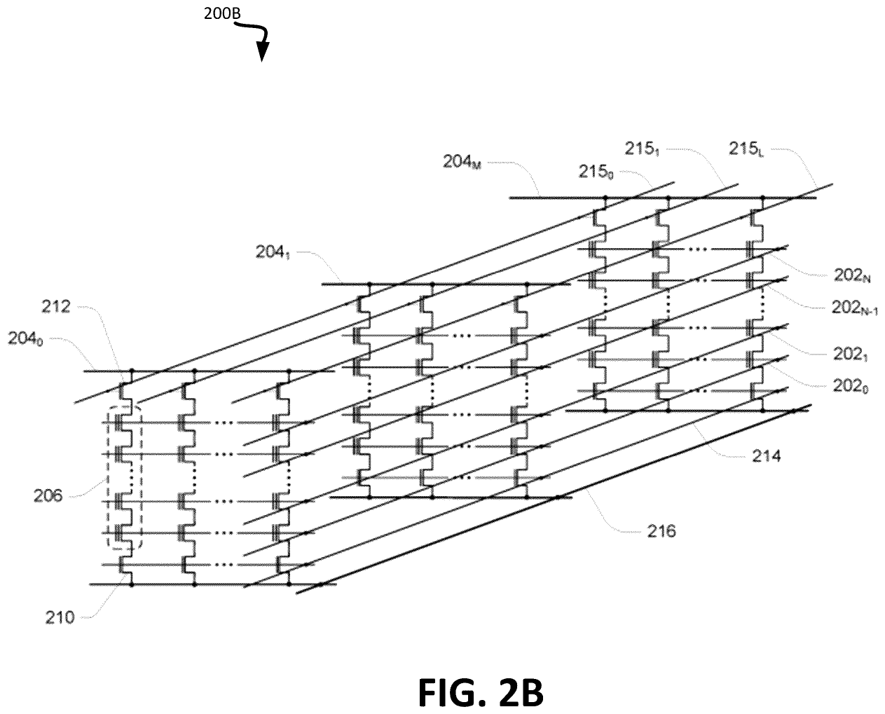

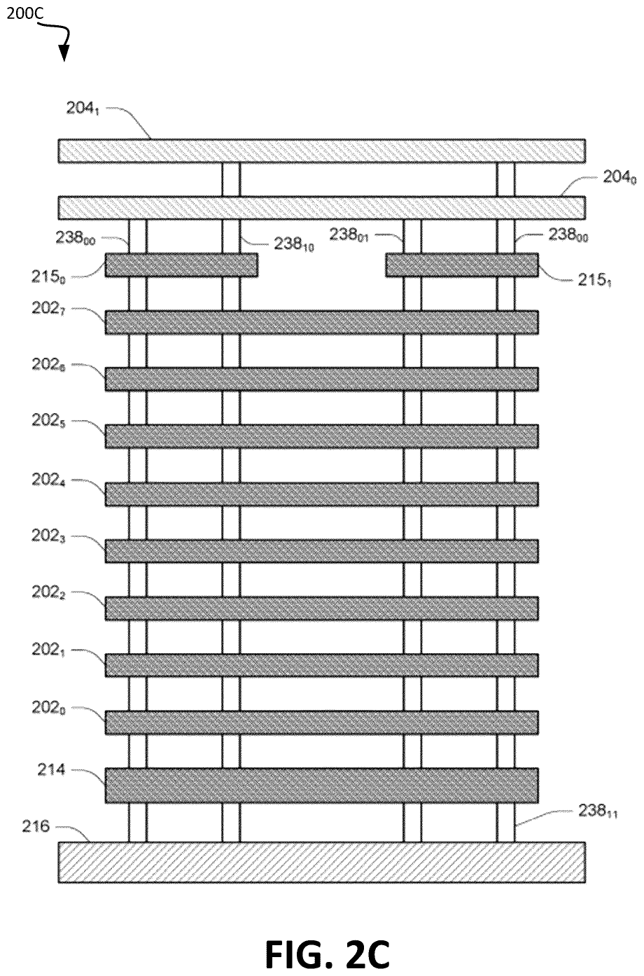

FIGS. 2A-2C are diagrams of portions of an example array of memory cells included in a memory device, in accordance with some embodiments of the present disclosure. For example, FIG. 2A is a schematic of a portion of an array of memory cells 200A as could be used in a memory device (e.g., as a portion of array of memory cells 104). Memory array 200A includes access lines, such as wordlines 202₀ to 202_{N}, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows each corresponding to a respective wordline 202 and columns each corresponding to a respective bitline 204. Rows of memory cells 208 can be divided into one or more groups of physical pages of memory cells 208, and physical pages of memory cells 208 can include every other memory cell 208 commonly connected to a given wordline 202. For example, memory cells 208 commonly connected to wordline 202_{N} and selectively connected to even bitlines 204 (e.g., bitlines 204₀, 204₂, 204₄, etc.) may be one physical page of memory cells 208 (e.g., even memory cells) while memory cells 208 commonly connected to wordline 202_{N} and selectively connected to odd bitlines 204 (e.g., bitlines 204₁, 204₃, 204₅, etc.) may be another physical page of memory cells 208 (e.g., odd memory cells). Although bitlines 204₃-204₅ are not explicitly depicted in FIG. 2A, it is apparent from the figure that the bitlines 204 of the array of memory cells 200A may be numbered consecutively from bitline 204₀ to bitline 204_{M}. Other groupings of memory cells 208 commonly connected to a given wordline 202 may also define a physical page of memory cells 208. For certain memory devices, all memory cells commonly connected to a given wordline might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells may include those memory cells that are configured to be erased together, such as all memory cells connected to wordlines 202₀-202_{N} (e.g., all strings 206 sharing common wordlines 202). Unless expressly distinguished, a reference to a page of memory cells herein refers to the memory cells of a logical page of memory cells.

Each column can include a string of series-connected memory cells (e.g., non-volatile memory cells), such as one of strings 206₀ to 206_{M}. Each string 206 can be connected (e.g., selectively connected) to a source line 216 (SRC) and can include memory cells 208₀ to 208_{N}. The memory cells 208 of each string 206 can be connected in series between a select gate 210, such as one of the select gates 210₀ to 210_{M}, and a select gate 212, such as one of the select gates 212₀ to 212_{M}. In some embodiments, the select gates 210₀ to 210_{M} are source-side select gates (SGS) and the select gates 212₀ to 212_{M} are drain-side select gates. Select gates 210₀ to 210_{M} can be connected to a select line 214 (e.g., source-side select line) and select gates 212₀ to 212_{M} can be connected to a select line 215 (e.g., drain-side select line). The select gates 210 and 212 might represent a plurality of select gates connected in series, with each select gate in series configured to receive a same or independent control signal. A source of each select gate 210 can be connected to SRC 216, and a drain of each select gate 210 can be connected to a memory cell 208₀ of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208_{N} of the corresponding string 206. Therefore, each select gate 212 might be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The three-dimensional memory array 200B may incorporate vertical structures which may include semiconductor pillars where a portion of a pillar may act as a channel region of the memory cells of strings 206. The strings 206 may be each selectively connected to a bit line 204₀-204_{M} by a select gate 212 and to the SRC 216 by a select gate 210. Multiple strings 206 can be selectively connected to the same bitline 204. Subsets of strings 206 can be connected to their respective bitlines 204 by biasing the select lines 215₀-215_{L} to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly connected to each other by a particular wordline 202 may collectively be referred to as tiers.

FIG. 2C is a diagram of a portion of an array of memory cells 200C (e.g., a portion of the array of memory cells 104). Channel regions (e.g., semiconductor pillars) 238₀₀ and 238₀₁ represent the channel regions of different strings of series-connected memory cells (e.g., strings 206 of FIGS. 2A-2B) selectively connected to the bitline 204₀. Similarly, channel regions 238₁₀ and 238₁₁ represent the channel regions of different strings of series-connected memory cells (e.g., NAND strings 206 of FIGS. 2A-2B) selectively connected to the bitline 204₁. A memory cell (not depicted in FIG. 2C) may be formed at each intersection of a wordline 202 and a channel region 238, and the memory cells corresponding to a single channel region 238 may collectively form a string of series-connected memory cells (e.g., a string 206 of FIGS. 2A-2B). Additional features might be common in such structures, such as dummy wordlines, segmented channel regions with interposed conductive regions, etc.

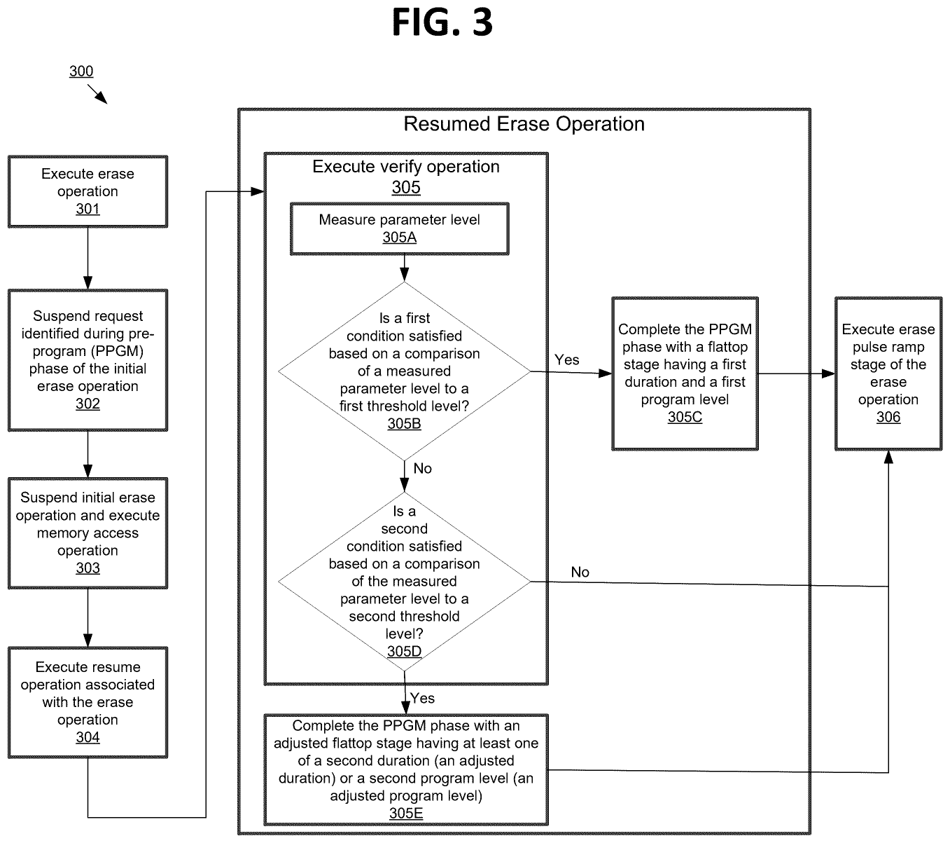

FIG. 3 illustrates an example flow diagram associated with a process 300 for resuming, by control logic (e.g., erase manager 137 of FIGS. 1A and 1B) a suspended erase operation associated with one or more memory cells of a memory device (e.g., memory device 130 of FIGS. 1A and 1B) of a memory sub-system (e.g., memory sub-system 110 of FIG. 1A), where the initial erase operation was previously suspended during a PPGM phase of the erase operation.

At operation 301, control logic executes an erase operation. In an embodiment, the erase operation is executed to erase a set of target memory cells of a memory device. In an embodiment, following completion of a partial-block erase (PBE) phase, the erase operation initiates the PPGM stage. In an embodiment, the PPGM phase includes application of a ramping voltage (i.e., a PPGM ramping voltage stage).

At operation 302, during the PPGM ramping voltage stage, control logic identifies a request to suspend the ongoing erase operation (also referred to as the “initial erase operation”). In an embodiment, the suspend request is initiated by a host system (e.g., host system 120 of FIG. 1A) to enable a different memory access operation to be executed (e.g., a higher priority memory access operation such as a program operation or a read operation). In response to the request, at operation 303, control logic suspends the initial erase operation to allow for the execution of the higher priority memory access operation.

At operation 304, following completion of the higher priority memory access operation, control logic initiates execution of a resume operation to resume the previously suspended erase operation. As shown in FIG. 3, at operation 305, control logic executes a verify operation. At operation 305A of the verify operation, control logic measures a parameter level associated with the set of target memory cells to be erased. In an embodiment, the parameter level is a measured CFByte associated with the set of target memory cells. In another embodiment, the parameter level is a measured threshold voltage associated with the set of target memory cells. For the purposes of illustration, the example shown in FIG. 3 is described with the measured parameter level including a measured CFByte level.

At operation 305B, control logic determines if the measured parameter level (e.g., the measured CFByte level) satisfies a first condition. In an embodiment, the first condition is satisfied if the measured parameter level is greater than a first threshold level (i.e., CFByte_high). In an embodiment, in response to determining that the first condition is satisfied (i.e., the measured parameter level is greater than the first threshold level (e.g., CFByte_high)), the process proceeds to operation 305C. In operation 305C, control logic causes the PPGM phase of the resumed erase operation to be completed with a flattop stage having a first duration and first program level. In an embodiment, the first duration and first program level of the flattop stage of the PPGM phase according to operation 305C is the same duration and same program level of the original erase operation initiated at operation 301 (i.e., the duration and program level of the flattop stage is not adjusted). Following completion of operation 305C (i.e., completing the PPGM phase with the flattop stage having the first duration and program level (i.e., original duration and program level), the process continues to operation 306. At operation 306, control logic causes execution of an erase pulse ramp stage of the resumed erase operation.

In an embodiment, if at operation 305B a determination is made that the first condition is not satisfied (i.e., the measured parameter level is less than the first threshold level), the process proceeds to operation 305D. At operation 305D, control logic determines if the measured parameter level (e.g., the measured CFByte level) satisfies a second condition. In an embodiment, the second condition is satisfied if the measured parameter level is greater than a second threshold level (i.e., CFByte_low). According to embodiments, the first threshold level (e.g., CFByte_high) is greater than the second threshold level (e.g., CFByte_low).

In an embodiment, in response to determining that the second condition is satisfied (i.e., the measured parameter level is greater than the second threshold level (e.g., CFByte_low)), the process proceeds to operation 305E. At operation 305E, control logic causes the PPGM phase of the resumed erase operation to be completed with an adjusted flattop stage having a second duration. In an embodiment, the second duration of the flattop stage of the PPGM phase is less than the first duration of the flattop stage of the PPGM phase. In an embodiment, the adjusted flattop stage includes a shorter duration as compared to the original erase operation which results in a reduction of overprogramming of the target memory cells being erased.

In another embodiment, at operation 305E, control logic causes the PPGM phase of the resumed erase operation to be completed with an adjusted flattop stage having a second program level. In this embodiment, if the first condition is not satisfied and the second condition is satisfied, the second program level of the flattop stage of the PPGM phase is less than the first program level of the flattop stage of the PPGM phase of a normal (non-suspended) erase operation. In an embodiment, the adjusted flattop stage includes a smaller program level as compared to the original erase operation which results in a reduction of overprogramming of the target memory cells being erased.

In an embodiment, in response to determining that the second condition is not satisfied (i.e., the measured parameter level is less than both the first threshold level (CFByte_high) and the second threshold level (CFByte_low)), the process continues to operation 306, where the control logic causes execution of an erase pulse ramp stage of the resumed erase operation (i.e., the PPGM phase of the erase operation is skipped).

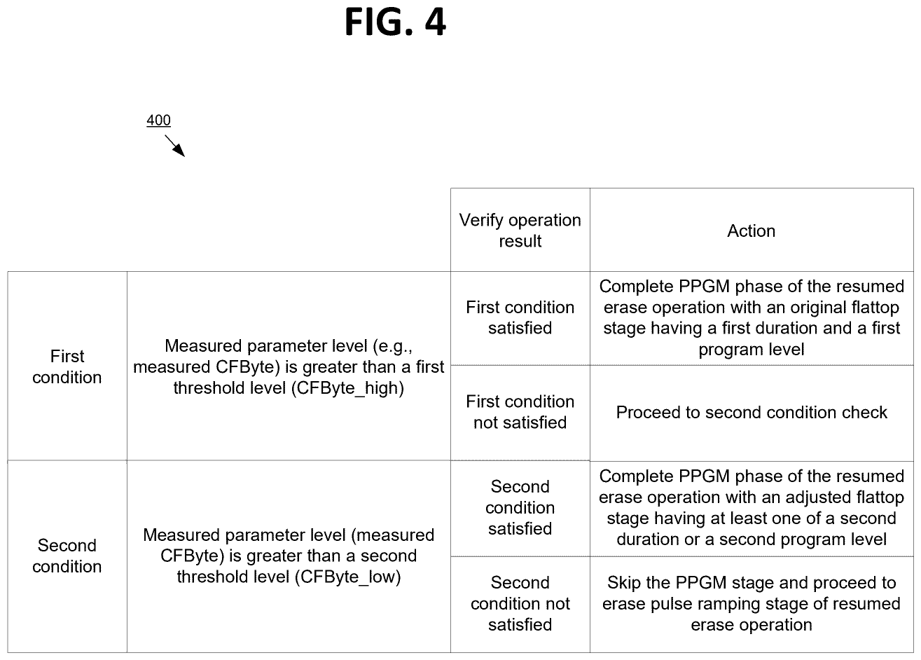

FIG. 4 depicts a table 400 representing an example verify operation executed by control logic (e.g., erase manager 137 of FIGS. 1A and 1B) during a resume operation associated with an erase operation suspended during a PPGM stage, according to one or more embodiments of the present disclosure. According to embodiments, the table 400 illustrates the operations and actions performed by the control logic during operations 305 and 306 of process 300 shown in FIG. 3.

As shown in FIG. 4, when resuming the suspended erase operation, control logic performs the verify operation to determine a measured parameter level (e.g., a measured CFByte level) and determines if a first condition is satisfied (i.e., is the measured parameter level greater than a first threshold level (e.g., CFByte_high). As shown in FIG. 4, if the first condition is satisfied, control logic executed the PPGM phase of the resumed erase operation with a flattop stage having a first duration (i.e., applying a “flattop” or constant voltage during the PPGM stage which has a first duration which is the same as the duration of the flattop stage of the original (suspended) erase operation). In an embodiment, if the first condition is satisfied, the flattop stage has a duration which is not adjusted (i.e., remains the same as the flattop stage associated with the original erase operation.)

As shown in FIG. 4, if the first condition is not satisfied, control logic proceeds to check a second condition where the measured parameter level is compared to a second threshold level (e.g., CFByte_low). In an embodiment, the first threshold level is greater than the second threshold level. If the second condition is satisfied (i.e., the measured parameter level is greater than the second threshold level), control logic executes the PPGM stage of the resumed erase operation with an adjusted flattop stage having a second duration or/and second program level. In an embodiment, the second duration of the adjusted flattop stage of the PPGM phase is less than the first duration of the original (i.e., non-adjusted) flattop stage of the PPGM phase. In another embodiment, the second program level of the adjusted flattop stage of the PPGM phase is less than the first program level of the original (i.e., non-adjusted) flattop stage of the PPGM phase. Advantageously, execution of the adjusted flattop stage reduces overprogramming of the memory cells being erased since those memory cells are subjected to a shorter duration of voltage in the flattop stage of the PPGM phase.

As shown in FIG. 4, according to embodiments, if the second condition is not satisfied, control logic causes the PPGM phase to be skipped and proceeds to the erase pulse ramping phase of the resumed erase operation.

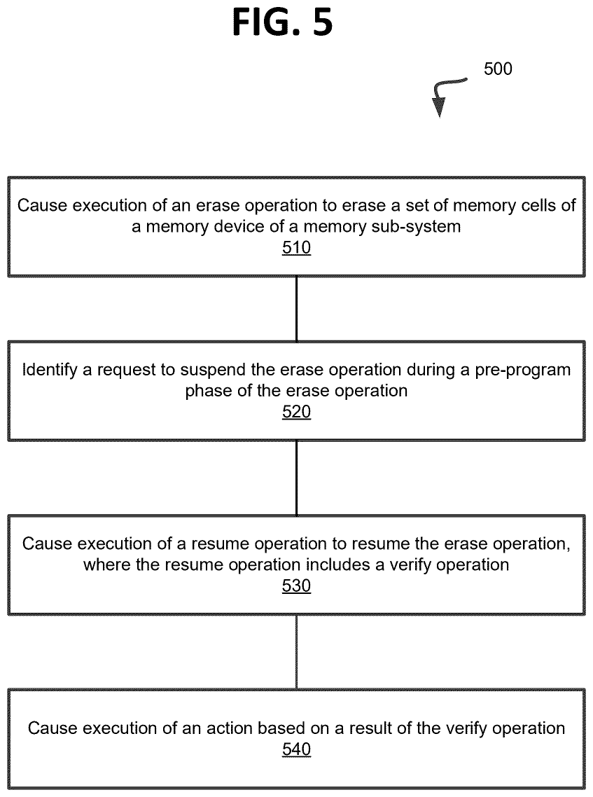

FIG. 5 is a flow diagram of a method 500 to cause execution of a resume operation to resume an erase operation that was previously suspended during a pre-program phase of the erase operation, where the resume operation includes performing an action based on a result of a verify operation, in accordance with some embodiments of the present disclosure. The method 500 can be performed by control logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the local media controller 135 and/or the erase manager 137 of FIGS. 1A-1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, an operation is executed. For example, control logic (e.g., erase manager 137 of FIGS. 1A and 1B) can cause execution of an erase operation to erase a set of memory cells of a memory device of a memory sub-system.

At operation 520, a request is identified. For example, control logic identify a request to suspend the erase operation during a pre-program (PPGM) phase of the erase operation. In an embodiment, the request to suspend is identified in response to a request from a host system to perform a media access operation. In an embodiment, in response to a request from the host system to perform the media access operation (e.g., a higher priority operation as compared to the in-progress erase operation), control logic identifies the request to suspend the erase operation and causes the erase operation to be suspended. According to embodiments, the erase operation is suspended during the PPGM phase of the erase operation.

At operation 530, an operation is executed. For example, control logic causes execution of a resume operation to resume the erase operation, where the resume operation includes a verify operation. In an embodiment, the verify operation (as described above with reference to FIGS. 3 and 4) includes measuring a parameter level (e.g., a CFByte level) associated with the set of memory cells to be erased. In an embodiment, the verify operation includes comparing the measured parameter level determine a result of the verify operation (i.e., whether a condition (e.g., a first condition or a second condition) is satisfied).

In an embodiment, the result of the verify operation includes a determination that the measured parameter level satisfies a first condition. In an embodiment, the result of the verify operation includes a determination that the measured parameter level does not satisfy the first condition and satisfies a second condition. In an embodiment, the result of the verify operation includes a determination that the measured parameter level does not satisfy either the first condition or the second condition.

At operation 540, an action is executed. For example, during the resume operation, control logic causes execution of an action based on the result of the verify operation (e.g., based on the result of the verify operation of operation 530). In an embodiment, in response to determining the result of the verify operation includes satisfaction of the first condition, the action includes executing the pre-program (PPGM) phase of the resumed erase operation with a flattop stage having a first duration. In an embodiment, the first duration of the flattop stage of the resumed erase operation is the same length as a flattop stage of the original (suspended) erase operation. In this embodiment, the action performed in response to satisfaction of the first condition includes executing the flattop stage of the resumed erase operation with the original (non-adjusted) duration. In an embodiment, following execution of the PPGM phase including the flattop stage having the first duration, the action further includes executing an erase pulse ramp stage of the erase operation.

At operation 540, if the result includes a determination that the first condition is not satisfied, the verify operation further includes determining if the second condition is satisfied. In an embodiment, in response to determining the result of the verify operation includes satisfaction of the second condition, the action includes executing the pre-program (PPGM) phase of the resumed erase operation with an adjusted flattop stage having a second duration or/and second program level (i.e., an adjusted duration/program level which is less than the first duration/first program level). In an embodiment, following execution of the PPGM phase including the adjusted flattop stage having the second duration, the action further includes executing the erase pulse ramp stage of the erase operation.

At operation 540, if the result of the verify operation includes a determination that neither the first condition nor the second condition are satisfied, the action includes skipping the PPGM stage of the erase operation and proceeding to execution of the erase pulse ramp stage of the erase operation. Further details regarding operations 510-540 are described above with reference to FIGS. 1A-4.

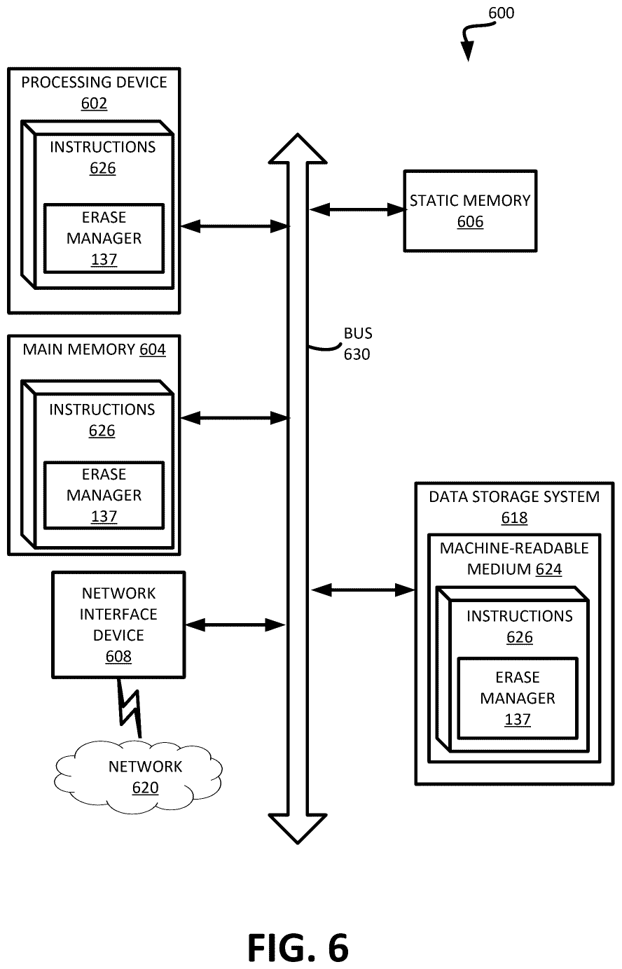

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the local media controller 135 and/or the erase manager 137 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a memory cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to a local media controller and/or PPM component (e.g., the local media controller 135 and/or the erase manager 137 of FIG. 1A). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array; and
control logic, operatively coupled with the memory array, to perform operations comprising:
causing execution of an erase operation to erase a set of memory cells of the memory array;
identifying a request to suspend the erase operation during a pre-program phase of the erase operation;
causing execution of a resume operation to resume the erase operation, wherein the resume operation comprises a verify operation; and
causing execution of an action based on a result of the verify operation.

2. The memory device of claim 1, wherein the verify operation comprises measuring a parameter level associated with the set of memory cells.

3. The memory device of claim 2, wherein the verify operation further comprises determining that the parameter level satisfies a first condition, wherein the first condition is satisfied when the parameter level is greater than a first threshold level.

4. The memory device of claim 3, wherein the action comprises executing the pre-program phase of the erase operation comprising a flattop stage having a first duration.

5. The memory device of claim 2, wherein the verify operation further comprises:
determining that the parameter level does not satisfy a first condition, wherein the first condition is not satisfied when the parameter level is less than a first threshold level; and
determining that the parameter level satisfies a second condition, wherein the second condition is satisfied when the parameter level is greater than a second threshold level, wherein the second threshold level is less than the first threshold level.

6. The memory device of claim 5, wherein the action comprises executing the pre-program phase of the erase operation comprising an adjusted flattop stage having a reduced duration.

7. The memory device of claim 5, wherein the action comprises executing the pre-program phase of the erase operation comprising an adjusted flattop stage having a reduced pre-program voltage.

8. The memory device of claim 2, wherein the verify operation further comprises:
determining that the parameter level does not satisfy a first condition, wherein the first condition is not satisfied when the parameter level is less than a first threshold level; and
determining that the parameter level does not satisfy a second condition, wherein the second condition is not satisfied when the parameter level is less than a second threshold level, wherein the second threshold level is less than the first threshold level.

9. The memory device of claim 8, wherein the action comprises skipping the pre-program phase of the erase operation being resumed.

10. A method comprising:
causing execution of an erase operation to erase a set of memory cells of a memory device;
identifying a request to suspend the erase operation during a pre-program phase of the erase operation;
causing execution of a resume operation to resume the erase operation, wherein the resume operation comprises a verify operation; and
causing execution of an action based on a result of the verify operation.

11. The method of claim 10, wherein the verify operation comprises measuring a parameter level associated with the set of memory cells.

12. The method of claim 11, further comprising determining that the parameter level satisfies a first condition, wherein the first condition is satisfied when the parameter level is greater than a first threshold level, wherein the action comprises executing the pre-program phase of the erase operation comprising a flattop stage having a first duration.

13. The method of claim 11, wherein the verify operation further comprises:
determining that the parameter level does not satisfy a first condition, wherein the first condition is not satisfied when the parameter level is less than a first threshold level; and
determining that the parameter level satisfies a second condition, wherein the second condition is satisfied when the parameter level is greater than a second threshold level, wherein the second threshold level is less than the first threshold level.

14. The method of claim 13, wherein the action comprises executing the pre-program phase of the erase operation comprising an adjusted flattop stage having a reduced duration.

15. The method of claim 13, wherein the action comprises executing the pre-program phase of the erase operation comprising an adjusted flattop stage having a reduced pre-program voltage.

16. The method of claim 11, wherein the verify operation further comprises:
determining that the parameter level does not satisfy a first condition, wherein the first condition is not satisfied when the parameter level is less than a first threshold level; and
determining that the parameter level does not satisfy a second condition, wherein the second condition is not satisfied when the parameter level is less than a second threshold level, wherein the second threshold level is less than the first threshold level, and wherein the action comprises skipping the pre-program phase of the erase operation being resumed.

17. A non-transitory computer-readable storage medium comprising instructions that, when executed by a processing device, cause the processing device to perform operations comprising:
causing execution of an erase operation to erase a set of memory cells of a memory device;
identifying a request to suspend the erase operation during a pre-program phase of the erase operation;
causing execution of a resume operation to resume the erase operation, wherein the resume operation comprises a verify operation; and
causing execution of an action based on a result of the verify operation.

18. The non-transitory computer-readable storage medium of claim 17, wherein the verify operation comprises:
measuring a parameter level associated with the set of memory cells; and
determining that the parameter level satisfies a first condition, wherein the first condition is satisfied when the parameter level is greater than a first threshold level, and wherein the action comprises executing the pre-program phase of the erase operation comprising a flattop stage having a first duration.

19. The non-transitory computer-readable storage medium of claim 17, wherein the verify operation comprises:
measuring a parameter level associated with the set of memory cells;
determining that the parameter level does not satisfy a first condition, wherein the first condition is not satisfied when the parameter level is less than a first threshold level; and
determining that the parameter level satisfies a second condition, wherein the second condition is satisfied when the parameter level is greater than a second threshold level, wherein the second threshold level is less than the first threshold level, and wherein the action comprises executing the pre-program phase of the erase operation comprising an adjusted flattop stage having at least one of a reduced duration or a reduced pre-program voltage.

20. The non-transitory computer-readable storage medium of claim 17, wherein the verify operation comprises:
measuring a parameter level associated with the set of memory cells;
determining that the parameter level does not satisfy a first condition, wherein the first condition is not satisfied when the parameter level is less than a first threshold level; and
determining that the parameter level does not satisfy a second condition, wherein the second condition is not satisfied when the parameter level is less than a second threshold level, wherein the second threshold level is less than the first threshold level, and wherein the action comprises skipping the pre-program phase of the erase operation being resumed.
